(19) United States
(12) Patent Application Publication
(10) Pub. No.: US 2026/0215277 A1
(43) Pub. Date: Jul. 23, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Taketoshi SHIKANO, Tokyo (JP); Fumihito KAWAHARA, Tokyo (JP); Riki KAJIYAMA, Tokyo (JP)

(73) Assignee: Mitsubishi Electric Corporation, Tokyo (JP)

(21) Appl. No.: 19/310,345

(22) Filed: Aug. 26, 2025

(30) Foreign Application Priority Data
Jan. 22, 2025 (JP) 2025-008940

(51) Int. Cl. H01L 23/00; H01L 21/66; H01L 23/373

(52) U.S. Cl. CPC H10W 42/121; H10P 74/203; H10W 40/258

(57) ABSTRACT

A semiconductor device includes: an insulating substrate having an insulating layer with a first main surface and a second main surface which is on the opposite side from the first main surface, a first metal layer bonded to the first main surface, and a second metal layer bonded to the second main surface; and a chip bonded to a second surface of the second metal layer, which is on the opposite side from a first surface of the second metal layer bonded to the insulating substrate, wherein the first metal layer has a region in which a size of a grain boundary on a second surface of the first metal layer, which is on the opposite side from a first surface of the first metal layer bonded to the insulating substrate, is smaller than a size of a grain boundary on the second surface of the second metal layer.

### BACKGROUND OF THE INVENTION

### Field

The present disclosure relates to a semiconductor device and a method of manufacturing the semiconductor device.

### Background

A semiconductor device uses a substrate, such as a direct bonded copper (DBC) substrate and an active metal brazed (AMB) substrate, which includes metal layers on both sides of an insulating substrate, and uses ceramics, such as aluminum nitride (ALN) and silicon nitride (Si3N4), and patterned copper plates placed on the top and bottom sides. On the substrate, a chip is mounted and wiring is implemented using another metal, such as aluminum (Al) and copper (Cu). When pattern etching is performed on a metal layer to cause the metal layer to perform a circuit function, the substrate is warped due to differences in area and volume between the front and back metal layers. Moreover, die bonding causes warpage of the substrate due to the difference in the linear expansion coefficient between the ceramic and the metal layers. Such a problematic substrate warpage causes problems: instability when mounting the substrate on a base plate; and, when the substrate is sealed by transfer molding or the like, a sealing resin flows around and forms resin burrs on the back surface due to the influence of the warpage, which leads to additional work such as removal of the burrs. Therefore, a structure that intentionally did not use an insulating substrate was adopted in some cases. (Patent Literature 1)

### CITATION LIST

### Patent Literature

Patent Literature 1: JP 2004-165281 A

### SUMMARY

### Technical Problem

In the prior art, etching or the like is performed on the metal layer to form a circuit pattern on the insulating substrate. Etching the metal layer produces differences in area, volume, and pattern between the upper and lower metal layers, which cause a thermal stress imbalance between the top and bottom of the substrate. The thermal stress imbalance may cause warpage of the insulating substrate in a step of die-bonding a chip and the like during an assembly step of the semiconductor device. The warpage of the insulating substrate caused in the assembly step may lead to problems, such as resin burrs occurring on the back surface of the substrate in a molding step.

Hence, an object of the present disclosure is to provide a semiconductor device capable of improving the warpage of an insulating substrate, and a method of manufacturing the semiconductor device.

### Solution to Problem

A semiconductor device according to the present disclosure includes: an insulating substrate having an insulating layer with a first main surface and a second main surface which is on the opposite side from the first main surface, a first metal layer bonded to the first main surface, and a second metal layer bonded to the second main surface; and a chip bonded to a second surface of the second metal layer, which is on the opposite side from a first surface of the second metal layer bonded to the insulating substrate, wherein the first metal layer has a region in which a size of a grain boundary on a second surface of the first metal layer, which is on the opposite side from a first surface of the first metal layer bonded to the insulating substrate, is smaller than a size of a grain boundary on the second surface of the second metal layer.

A semiconductor device according to the present disclosure includes: an insulating substrate having an insulating layer with a first main surface and a second main surface which is on the opposite side from the first main surface, a first metal layer bonded to the first main surface, and a second metal layer bonded to the second main surface; and a chip bonded to a second surface of the second metal layer, which is on the opposite side from a first surface of the second metal layer bonded to the insulating substrate, wherein the first metal layer has a region in which a size of a grain boundary on a second surface of the first metal layer, which is on the opposite side from a first surface of the first metal layer bonded to the insulating substrate, is smaller than a size of a grain boundary on the first surface of the first metal layer.

A method of manufacturing the semiconductor device according to the present disclosure includes: a preparation step of preparing a chip and an insulating substrate having an insulating layer with a first main surface and a second main surface which is on the opposite side from the first main surface, a first metal layer bonded to the first main surface; and a second metal layer bonded to the second main surface; a die bonding step of die-bonding the chip to a second surface of the second metal layer, which is on the opposite side from a first surface of the second metal layer bonded to the insulating substrate; and a peening step of peening on a portion including at least a second surface of the first metal layer, which is on the opposite side from a first surface of the first metal layer bonded to the insulating substrate.

### Advantageous Effects of Invention

In the semiconductor device of the present disclosure, since the second surface of the first metal layer on the opposite side has a region where the grain boundary is smaller than that on the second surface of the second metal layer on which the chip is bonded, the second surface of the first metal layer is stretched more than the second surface of the second metal layer, thereby reducing the concave warpage of the first metal layer of the insulating substrate.

In the semiconductor device of the present disclosure, since the second surface of the first metal layer has a region where the grain boundary is smaller than that on the first surface of the first metal layer, the second surface of the first metal layer is stretched more than the first surface of the first metal layer, thereby reducing the concave warpage of the first metal layer of the insulating substrate.

In the method of manufacturing the semiconductor device of the present disclosure, by performing the peening process on the second surface of the first metal layer, the grain boundary on the second surface is reduced, and the second surface of the first metal layer can be stretched. By performing the peening process on the second surface of the first metal layer after die bonding at which the warpage becomes maximum, the convex warpage on the second metal layer side of the insulating substrate can be reduced.

### BRIEF DESCRIPTION OF DRAWINGS

FIG. 1 is a schematic cross-sectional view with an emphasis on the warpage of a semiconductor device in a comparative example of the first embodiment.

FIG. 2 is a schematic cross-sectional view with an emphasis on the warpage of the semiconductor device after a die bonding step in the comparative example of the first embodiment.

FIG. 3 is a schematic perspective view with an emphasis on the warpage of the semiconductor device after the die bonding step in the comparative example of the first embodiment.

FIG. 4 is a rear view of the semiconductor device in the comparative example of the first embodiment.

FIG. 5 is a cross-sectional view of a semiconductor device after a peening step of the first embodiment.

FIG. 6 is a cross-sectional view of the semiconductor device of the first embodiment.

FIG. 7 is a cross-sectional view illustrating a peening process in a method of manufacturing the semiconductor device of the first embodiment.

FIG. 8 is a flowchart of steps in a manufacturing method of the first embodiment.

FIG. 9 is a flowchart of steps in a manufacturing method of a second embodiment.

### DESCRIPTION OF EMBODIMENTS

### 1. First Embodiment

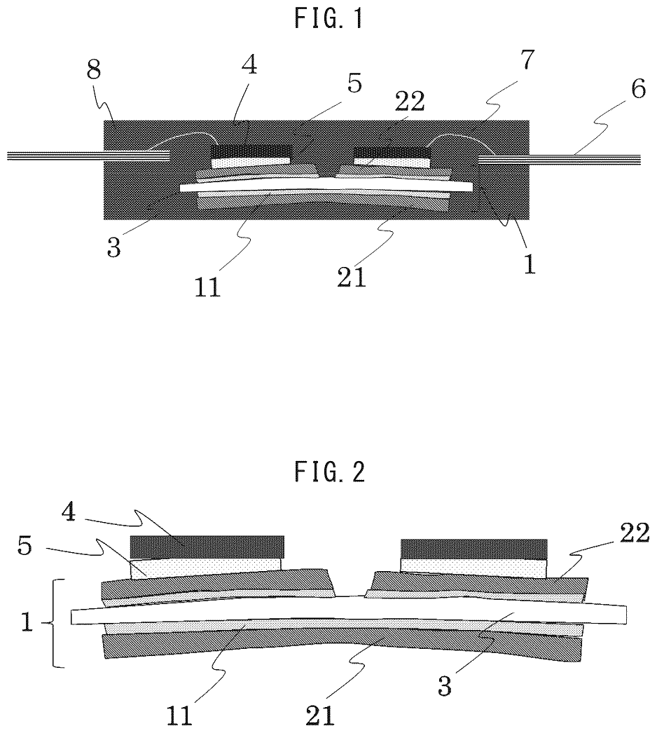

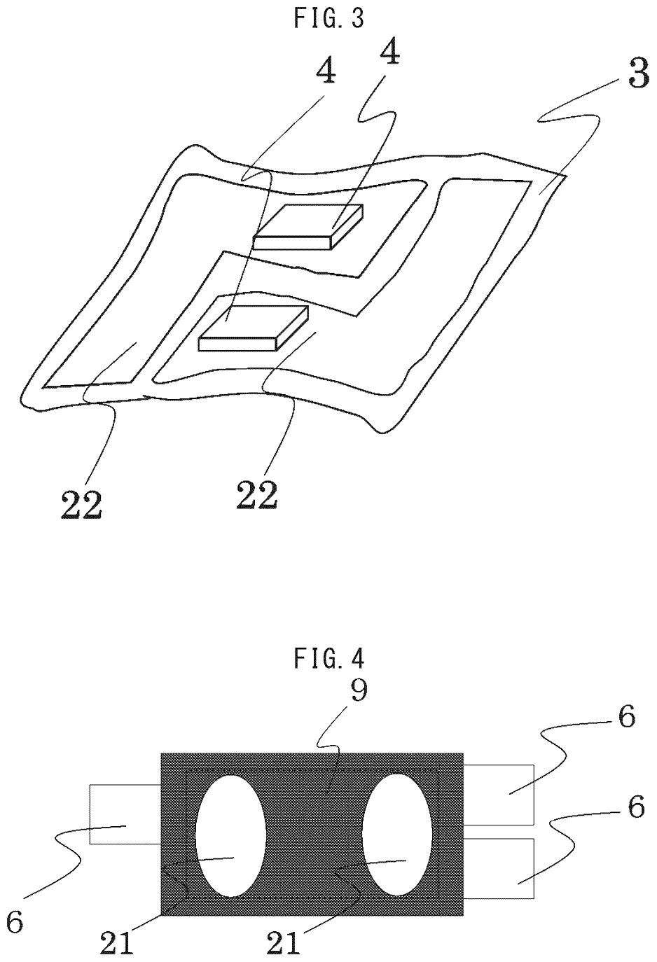

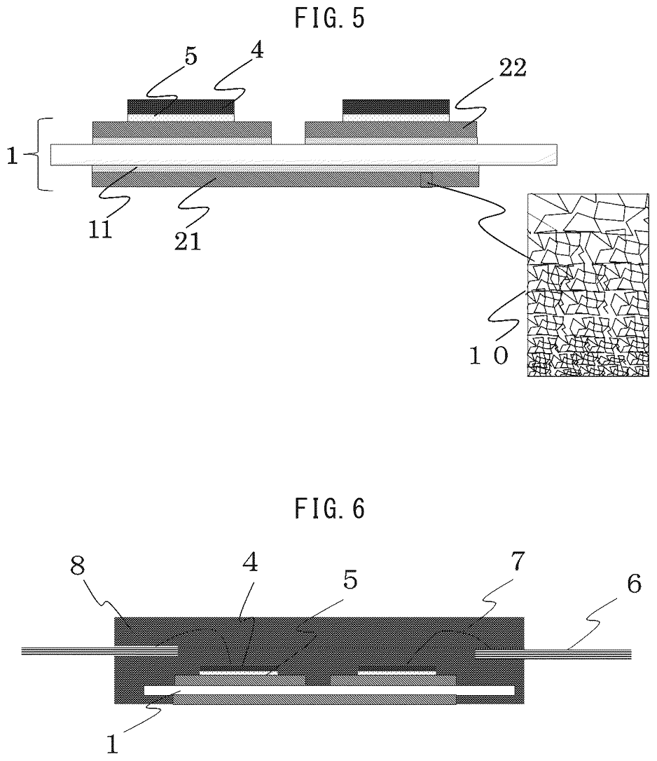

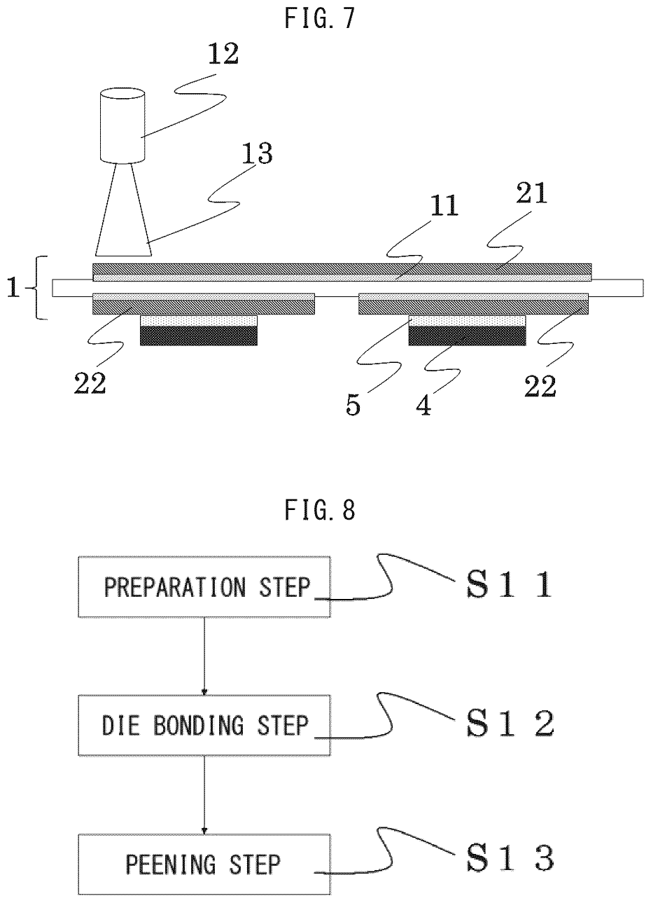

A semiconductor device according to a first embodiment will be described with reference to the drawings. FIG. 1 is a schematic cross-sectional view with an emphasis on the warpage of a semiconductor device in a comparative example of the first embodiment. FIG. 2 is a schematic cross-sectional view with an emphasis on the warpage of the semiconductor device after a die bonding step in the comparative example of the first embodiment. FIG. 3 is a schematic perspective view with an emphasis on the warpage of the semiconductor device after the die bonding step in the comparative example of the first embodiment. FIG. 4 is a rear view of the semiconductor device in the comparative example of the first embodiment. FIG. 5 is a cross-sectional view of a semiconductor device after a peening step of the first embodiment. FIG. 6 is a cross-sectional view of the semiconductor device of the first embodiment. FIG. 7 is a cross-sectional view illustrating a peening process in a method of manufacturing the semiconductor device of the first embodiment.

### 1-1. Configuration of Semiconductor Device

The semiconductor device of the present embodiment includes: an insulating substrate 1 having an insulating layer 3 with a first main surface and a second main surface which is on the opposite side from the first main surface, a first metal layer 21 bonded to the first main surface, and a second metal layer 22 bonded to the second main surface; and a chip 4 bonded to a second surface of the second metal layer 22, which is on the opposite side from a first surface of the second metal layer 22 bonded to the insulating substrate 1. In the present embodiment, the first metal layer 21 has a region in which the size of a grain boundary 10 on a second surface of the first metal layer 21, which is on the opposite side from a first surface of the first metal layer 21 bonded to the insulating substrate 1, is smaller than the size of the grain boundary 10 on the second surface of the second metal layer 22 on the opposite side from the first surface thereof bonded to the insulating substrate 1.

### Insulating Substrate 1

The insulating substrate 1 of the present embodiment has the semiconductor chip 4 bonded to the surface on one side, and is made of material such as ceramics and resin. The insulating substrate 1 and the semiconductor chip 4 are bonded using a bonding material b11 such as a brazing material and solder. A circuit pattern is formed on the second metal layer 22. For example, the circuit pattern is produced by etching copper or the like, which is the material of the second metal layer 22.

In the present embodiment, the insulating substrate 1 is constituted by the metal layers and the insulating layer 3. In the insulating substrate 1, the first metal layer 21, the insulating layer 3, and the second metal layer 22 are stacked in this order, and the insulating layer 3 is interposed between the two metal layers. As described above, each metal layer is mainly made of copper material, and the circuit pattern is formed. The insulating layer 3 is made of a ceramic material having insulating properties, such as alumina. By interposing an insulator between two kinds of metal layers, electrical circuits constituted by two kinds of circuit boards, respectively, do not interfere with each other, thereby preventing short circuits and electrical problems.

As described above, the bonding material b11 is provided on both surfaces of the insulating layer 3 (the first surface of the first metal layer 21 and the first surface of the second metal layer 22). Although a brazing material is mainly used for the bonding material b11, solder and a sintering material using a metal paste such as silver paste may be used.

The present embodiment includes the chip 4 bonded to the second surface of the second metal layer 22, which is on the opposite side from the first surface of the second metal layer 22 bonded to the insulating substrate 1. In other words, the semiconductor chip 4 or a capacitor chip 4 is attached through a bonding material a5 to the second surface of the second metal layer 22. In the semiconductor device, a heat spreader plate is attached to a surface on the opposite side from the side on which the semiconductor chip 4 and the like are attached.

### Chip 4

The chip 4 of the present embodiment is bonded to the second surface of the second metal layer 22 having the circuit pattern. An insulated gate bipolar transistor (IGBT) or the like is used for the semiconductor chip 4. The IGBT is used for high voltage, high current switching, and is utilized for motor control, an inverter circuit, etc. The type of the semiconductor chip 4 is not limited to IGBT, and other types such as a diode and a metal-oxide-semiconductor field-effect transistor (MOSFET) may be used.

The semiconductor chip 4 is connected to an electrode 6 using a bonding wire 7. For example, copper or aluminum is used for the bonding wire 7.

The semiconductor chip 4 is bonded to the second surface of the second metal layer 22. In the present embodiment, the semiconductor chip 4 is attached to the second surface of the second metal layer 22 through the bonding material a5.

One end of the bonding wire 7 is bonded to a surface of the semiconductor chip 4 on the opposite side from the second metal layer 22. The other end of the bonding wire 7 is bonded to an external terminal. The semiconductor chip 4 is electrically connected to the outside by bonding the bonding wire 7 to the external terminal.

### Other Configurations of Semiconductor Device

As described above, one end of the bonding wire 7 is attached to a portion on the second surface of the second metal layer 22 on which the semiconductor chip 4 is bonded. The other end of the bonding wire 7 is connected to one end of the electrode 6. The semiconductor chip 4 is connected through the bonding wire 7 to the electrode 6, which is an external terminal. The external terminal extends to the outside of a sealing material 8, and the other end of the external terminal is exposed to the outside from the sealing material 8. By bringing the external terminal exposed to the outside into contact with another component, the external terminal can be connected to the external component.

In the present embodiment, the semiconductor device is filled with the sealing material 8 such that the sealing material 8 entirely covers the chip 4, the insulating substrate 1 and the bonding wire 7 to protect the chip 4, the insulating substrate 1, and so on.

### First Metal Layer 21

As described above, in the insulating substrate 1 for use in a semiconductor device or the like, metal layers, such as copper or aluminum, are bonded to both surfaces of the insulating layer 3, such as a ceramic layer, by the bonding material b11 such as a brazing material.

As illustrated in FIGS. 1 to 3, the first metal layer 21 described in the comparative example of the present embodiment is bonded to the surface on the other side of the insulating layer 3. The first metal layer 21 has warpage on the second surface. For the first metal layer 21, copper or aluminum is used as the main material. In the comparative example of the present embodiment, the warpage of the first metal layer 21 is a concave warpage with a protruding height decreasing toward the center.

### Second Metal Layer 22

As described above, the circuit pattern is formed by etching or the like on the second metal layer 22 to which the chip 4, wiring or the like is bonded. Therefore, when the area or volume balance of the metal layers on the back and front of the insulating substrate 1 changes, the substrate generally tends to warp. The second metal layer 22 side where a portion has been removed by etching or the like stretches, and the second metal layer 22 side of the insulating substrate 1 is convexly warped with the protruding height increasing toward the center, whereas the first metal layer 21 side of the insulating substrate 1 is a concavely warped with the protruding height decreasing toward the center.

Moreover, the insulating substrate 1 may not only be simply warped, but also be deformed in a twisted manner depending on an etching pattern. This phenomenon seems to be caused by two reasons: materials having different thermal expansion coefficients are stacked; and the volume or area balance of the metal layers of the insulating substrate 1 is lost due to etching or the like.

In the present embodiment, the circuit pattern is formed on the second metal layer 22 to which the chip 4 is bonded, and no circuit pattern is formed on the first metal layer 21. Therefore, the volume or area balance of the metal layers on both surfaces of the insulating substrate 1 is lost due to the etching or the like performed only on the second metal layer 22. The thermal stress balance is lost, which will cause the insulating substrate 1 to warp or twist.

Moreover, in the present embodiment, materials with different linear expansion coefficients, such as the metal layers made of copper or the like and the insulating layer 3 made of ceramic or the like, are stacked. Thermal stresses occur as a physical phenomenon through a process in which the materials with different linear expansion coefficients are bonded at a high temperature and then cooled. When the metal layers on both surfaces of the insulating substrate 1 are balanced in terms of area and volume, the thermal stresses are balanced and no warpage will occur.

For example, the linear expansion coefficient of silicon nitride (Si3N4) used for the insulating layer 3 is approximately 2.8×10−6/° C., and the linear expansion coefficient of a copper plate or like used for the metal layer is approximately 16.5×10−6/° C. Since the difference in linear expansion coefficient between the insulating layer 3 and the metal layer is about 5 times or more, warpage occurs in the comparative example of the first embodiment as illustrated in FIGS. 1 to 3.

Further, the chip 4 is bonded to the insulating substrate 1 after a die bonding step. Since the linear expansion coefficient of the chip 4 is approximately 2.6×10−6/° C., the second metal layer 22 to which the chip 4 is bonded in the semiconductor device of the present disclosure is convexly warped, and the amount of warpage is larger.

When the semiconductor device is assembled in a state in which the semiconductor device has warpage, stress due to the warpage of the insulating substrate 1 is generated in the bonding material a5, which is a die-bonding material.

FIG. 4 illustrates a state in which a resin burr 9 was formed on the surface of the insulating substrate 1 on the second metal layer 22 side in a transfer molding step in which the semiconductor device is filled with the sealing material 8. As described above, when assembling is performed in a state in which the semiconductor device has warpage, there is a concern that defects such as the resin burr 9 may occur and quality may be lowered. The present disclosure is proposed to solve the warpage problem and quality issue.

### Grain Boundary 10 in Metal Layers

In the present embodiment, the first metal layer 21 has a region in which the size of the grain boundary 10 on the second surface of the first metal layer 21, which is on the opposite side from the first surface of the first metal layer 21 bonded to the insulating substrate 1, is smaller than the size of the grain boundary 10 on the second surface of the second metal layer 22, which is on the opposite side from the first surface of the second metal layer 22 bonded to the insulating substrate 1.

With this configuration, since the second surface of the first metal layer 21 on the opposite side has a region where the grain boundary is smaller than that on the second surface of the second metal layer 22 on which the chip 4 is bonded, the second surface of the first metal layer 21 is stretched more than the second surface of the second metal layer 22, thereby reducing the convex warpage on the second metal layer 22 side of the insulating substrate 1.

In the present embodiment, by performing the peening process on the second surface of the first metal layer 21 as described later, the grain boundary on the second surface of the first metal layer 21 becomes smaller, and the second surface of the first metal layer 21 is compressed and stretched. Moreover, plastic deformation occurs in the second surface of the first metal layer 21, and compressive stress is generated in the second surface. Simultaneously, since the hardness of the first metal layer 21 increases, the fatigue strength can be increased.

In the present embodiment, the size of the grain boundary 10 on the second surface of the second metal layer 22 is equal to the size of the grain boundary 10 on the first surface of the second metal layer 22.

According to this configuration, the size of the grain boundary 10 is the same on the second surface and the first surface of the second metal layer 22, the second surface of the second metal layer 22 is not stretched, and the warpage will not increase. In other words, the peening process is not performed on the second surface of the second metal layer 22. In addition, since the peening process does not need to be performed on the entire first metal layer 21, the processing step can be shortened.

In the present embodiment, the first metal layer 21 and the second metal layer 22 are made of the same material. According to this configuration, the thermal expansion in the first metal layer 21 and the second metal layer 22 at both ends of the insulating substrate 1 can be maintained uniform, thereby maintaining the state of reduced warpage against temperature changes.

Addition of Characteristics of Claim 4 and Advantageous Effect of Paragraph 0010

As illustrated in FIG. 5, by applying the peening process to the second surface of the first metal layer 21, the grain boundary 10 in the second metal layer 22 is gradually reduced from the first surface toward the second surface. Consequently, it is possible to continuously increase the stretching effect from the first surface toward the second surface and reduce the internal stress deviation in the first metal layer 21.

### 1-2. Manufacturing Method

FIG. 8 illustrates a flowchart for explaining a method of manufacturing the semiconductor device.

### Preparation Step

First, in a preparation step S11, the chip 4 and the insulating substrate 1 having: the insulating layer 3 with the first main surface and the second main surface which is on the opposite side from the first main surface; the first metal layer 21 bonded to the first main surface; and the second metal layer 22 bonded to the second main surface are prepared. The configurations of the prepared members are as described above, and therefore the explanation thereof will be omitted.

### Die Bonding Step

In a die bonding step S12, the chip 4 is die-bonded to the second surface of the second metal layer 22, which is on the opposite side from the first surface of the second metal layer 22 bonded to the insulating substrate 1. In other words, the chip 4 is bonded to the insulating substrate 1 using the bonding material a5, which is a die-bonding material.

According to this configuration, although the chip 4 is bonded to the insulating substrate 1, the linear expansion coefficient of the chip 4 is approximately 2.6×10−6/° C., and, therefore, in the semiconductor device of the present disclosure, the second metal layer 22 side on which the chip 4 is bonded is convexly warped, and the warpage amount is larger.

When the semiconductor device is assembled in a state in which the semiconductor device has warpage, stress due to the warpage of the insulating substrate 1 is generated in the bonding material a5, which is a die-bonding material.

### Peening Step

In a peening step S13, peening is performed on a portion including at least the second surface of the first metal layer 21, which is on the opposite side from the first surface of the first metal layer 21 bonded to the insulating substrate 1.

According to this configuration, by performing the peening process on the second surface of the first metal layer 21, the grain boundary on the second surface is reduced, and the second surface of the first metal layer 21 can be stretched. By performing the peening process on the second surface of the first metal layer 21 after die bonding at which the warpage becomes maximum, the convex warpage on the second metal layer 22 side of the insulating substrate 1 can be reduced.

FIG. 7 illustrates the state of the semiconductor device of the present embodiment in the peening step. In the present embodiment, the peening step is performed using shot peening in which a nozzle 12 emits fine particles 13 toward the second metal layer 22. In shot peening, the surface is compressed and stretched by causing minute particles to strike the surface at high speed. At this time, the grain boundary is reduced due to plastic deformation. Moreover, work hardening is caused by plastic deformation.

In the peening step, laser peening may be performed. In laser peening, compressive residual stress is generated by applying a laser beam to the surface, and the surface is stretched. At this time, the grain boundary is reduced.

The semiconductor device of the present embodiment as illustrated in FIGS. 5 to 7 is completed by performing the steps as described above.

According to the manufacturing method, by performing the peening process on the second surface of the first metal layer 21, the second surface of the first metal layer 21 is stretched, and the concave warpage of the first metal layer 21 of the insulating substrate 1 can be reduced.

### 2. Second Embodiment

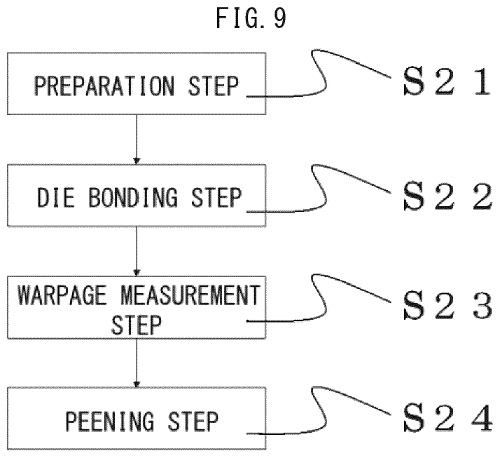

FIG. 9 is a flowchart of steps in a manufacturing method of a second embodiment.

In the present embodiment, unlike the first embodiment, the method further includes, between the die bonding step and the peening step, a warpage measurement step S23 for measuring the warpage of the insulating substrate 1. Since parts other than those related to the warpage measurement step 23 are the same as those in the first embodiment, the explanation thereof will be omitted.

As shown in FIG. 9, the method further includes, between a die bonding step S22 and a peening step S24, the warpage measurement step S23 for measuring the warpage of the insulating substrate 1. In the peening step S24, the amount of peening and a portion subjected to peening are determined based on the warpage measured in the warpage measurement step S23.

According to this configuration, since the amount of peening and the portion subjected to peening are determined depending on the warpage measured in the warpage measurement step S23, the warpage can be appropriately corrected even when the degree of the warpage and the tendency of the warpage change.

In the present embodiment, in the peening step S22, the amount of peening is increased in a region of the second surface of the first metal layer 21 having concave warpage measured in the warpage measurement step S23. According to this configuration, even when the degree of concave warpage changes at points on the second surface of the first metal layer 21, the concave warpage can be appropriately corrected by increasing the amount of peening in the region having the concave warpage.

For example, in the warpage measurement step S23, the degree of concave warpage at points on the second surface of the first metal layer 21 is measured. In the peening step S22, the amount of peening is calculated for the respective points, based on the degree of concave warpage at the respective points, and the peening process is performed on the respective points, based on the amount of peening for the respective points. As the amount of concave warpage at the points increases, the amount of peening for the points is increased. For example, the amount of peening for each point is adjusted by the duration of the peening process for each point and the intensity of the peening process for each point (for example, the particle injection amount or injection intensity, or the laser intensity). The peening process is not performed on points having no warpage.

Further warpage occurs in the die bonding step S22, but, when the size of the chip 4 is large or when a plurality of chips 4 are die-bonded, there are points where thermal stress is locally applied, and the warpage tendency is complex. Therefore, in order to more accurately correct the warpage, the warpage is actually measured linearly or planarly after the die bonding step S22 to measure the amount of the warpage, and the amount of peening for the respective points is changed to enable the correction of the complex warpage.

The present disclosure describes various exemplary embodiments and examples. Various features, aspects, and functions described in one or a plurality of embodiments are not limited to the applications of specific embodiments, and can be applied solely or in various combinations to the embodiments. Hence, innumerable modifications that are not exemplary illustrated are considered within the scope of the technology disclosed in the present disclosure. For example, these modifications include cases in which at least one component is modified, added, or omitted, and cases in which at least one component is extracted and combined with a component of another embodiment.

### REFERENCE SIGNS LIST

1 insulating substrate; 3 insulating layer; 4 chip; 5 bonding material a; 6 electrode; 7 bonding wire; 8 sealing material; 9 resin burr; 10 grain boundary; 11 bonding material b; 12 nozzle; 13 fine particle; 21 first metal layer; 22 second metal layer

Obviously many modifications and variations of the present disclosure are possible in the light of the above teachings. It is therefore to be understood that within the scope of the appended claims the invention may be practiced otherwise than as specifically described.

The entire disclosure of Japanese Patent Application No. 2025-008940, filed on Jan. 22, 2025 including specification, claims, drawings and summary, on which the convention priority of the present application is based, is incorporated herein by reference in its entirety.

1. A semiconductor device comprising:
an insulating substrate having an insulating layer with a first main surface and a second main surface which is on the opposite side from the first main surface, a first metal layer bonded to the first main surface, and a second metal layer bonded to the second main surface; and
a chip bonded to a second surface of the second metal layer, which is on the opposite side from a first surface of the second metal layer bonded to the insulating substrate,
wherein the first metal layer has a region in which a size of a grain boundary on a second surface of the first metal layer, which is on the opposite side from a first surface of the first metal layer bonded to the insulating substrate, is smaller than a size of a grain boundary on the second surface of the second metal layer.

2. The semiconductor device according to claim 1, wherein the first metal layer has a region in which a size of a grain boundary on the second surface of the first metal layer is smaller than a size of a grain boundary on the first surface of the first metal layer.

3. The semiconductor device according to claim 1, wherein the first metal layer and the second metal layer are made of the same material.

4. The semiconductor device according to claim 1, wherein a size of a grain boundary on the second surface of the second metal layer is equal to a size of a grain boundary on the first surface of the second metal layer.

5. The semiconductor device according to claim 2, wherein a size of a grain boundary on the second surface of the second metal layer is equal to a size of a grain boundary on the first surface of the second metal layer.

6. The semiconductor device according to claim 3, wherein a size of a grain boundary on the second surface of the second metal layer is equal to a size of a grain boundary on the first surface of the second metal layer.

7. The semiconductor device according to claim 1, wherein a circuit pattern is formed on the second metal layer, and a circuit pattern is formed on the first metal layer.

8. The semiconductor device according to claim 2, wherein a circuit pattern is formed on the second metal layer, and a circuit pattern is formed on the first metal layer.

9. The semiconductor device according to claim 3, wherein a circuit pattern is formed on the second metal layer, and a circuit pattern is formed on the first metal layer.

10. A semiconductor device comprising:
an insulating substrate having an insulating layer with a first main surface and a second main surface which is on the opposite side from the first main surface, a first metal layer bonded to the first main surface, and a second metal layer bonded to the second main surface; and
a chip bonded to a second surface of the second metal layer, which is on the opposite side from a first surface of the second metal layer bonded to the insulating substrate,
wherein the first metal layer has a region in which a size of a grain boundary on a second surface of the first metal layer, which is on the opposite side from a first surface of the first metal layer bonded to the insulating substrate, is smaller than a size of a grain boundary on the first surface of the first metal layer.

11. The semiconductor device according to claim 10, wherein a size of a grain boundary on the second surface of the second metal layer is equal to a size of a grain boundary on the first surface of the second metal layer.

12. The semiconductor device according to claim 10, wherein a circuit pattern is formed on the second metal layer, and a circuit pattern is formed on the first metal layer.

13. A method of manufacturing a semiconductor device comprising:
a preparation step for preparing a chip and an insulating substrate having an insulating layer with a first main surface and a second main surface which is on the opposite side from the first main surface, a first metal layer bonded to the first main surface; and a second metal layer bonded to the second main surface;
a die bonding step for die-bonding the chip to a second surface of the second metal layer, which is on the opposite side from a first surface of the second metal layer bonded to the insulating substrate; and
a peening step for peening on a portion including at least a second surface of the first metal layer, which is on the opposite side from a first surface of the first metal layer bonded to the insulating substrate.

14. The method of manufacturing a semiconductor device according to claim 13, further comprising a warpage measurement step for measuring a warpage of the insulating substrate between the die bonding step and the peening step,
wherein in the peening step, an amount of peening and a portion subjected to peening are determined based on the warpage measured in the warpage measurement step.

15. The method of manufacturing a semiconductor device according to claim 14, wherein in the peening step, the amount of peening is increased in a region of the second surface of the first metal layer having concave warpage measured in the warpage measurement step.

16. The method of manufacturing a semiconductor device according to claim 13, wherein the peening step is performed using shot peening or laser peening.

17. The method of manufacturing a semiconductor device according to claim 14, wherein the peening step is performed using shot peening or laser peening.

18. The method of manufacturing a semiconductor device according to claim 15, wherein the peening step is performed using shot peening or laser peening.
